(19) United States
(12) Patent Application Publication
(10) Pub. No.: US 2024/0123546 A1
(43) Pub. Date: Apr. 18, 2024

(54) LASER PROCESSING APPARATUS AND LASER PROCESSING METHOD

(71) Applicant: DISCO CORPORATION, Tokyo (JP)

(72) Inventors: Naotoshi KIRIHARA, Tokyo (JP); Hiroshi MORIKAZU, Tokyo (JP); Yohei KANEKO, Tokyo (JP); Kentaro ODANAKA, Tokyo (JP)

(21) Appl. No.: 18/486,625

(22) Filed: Oct. 13, 2023

(30) Foreign Application Priority Data
Oct. 14, 2022 (JP) 2022-165458

(51) Int. Cl. B23K 26/082; B23K 26/06

(52) U.S. Cl. CPC B23K 26/082; B23K 26/0665; B23K 2101/42

(57) ABSTRACT

A laser processing apparatus includes a chuck table that holds a workpiece, a laser beam irradiation unit that irradiates the workpiece with a laser beam, and a feed mechanism that moves the chuck table and the laser beam irradiation unit relative to each other to execute processing feed. The laser beam irradiation unit includes a laser oscillation mechanism that emits a pulsed laser beam and a beam condenser that condenses the pulsed laser beam emitted by the laser oscillation mechanism and irradiates the workpiece with the pulsed laser beam. The laser oscillation mechanism has a group setting part that sets multiple pulsed laser beams into one group and a time interval setting part that sets a time interval of the pulsed laser beams that configure the one group, and sets the repetition frequency in such a manner as to regard the one group as one unit.

### BACKGROUND OF THE INVENTION

### Field of the Invention

The present invention relates to a laser processing apparatus and a laser processing method in which processing is executed for a workpiece.

### Description of the Related Art

A wafer on which multiple devices such as integrated circuits (ICs) and large-scale integrations (LSIs) are formed on a front surface in such a manner as to be marked out by multiple planned dividing lines that intersect each other is divided into individual device chips by a laser processing apparatus, and the respective device chips obtained by the dividing are used for pieces of electrical equipment such as mobile phones and personal computers.

The laser processing apparatus includes a chuck table that holds a workpiece, a laser beam irradiation unit that executes irradiation with a laser beam with a wavelength having absorbability with respect to the workpiece held by the chuck table, and a feed mechanism that moves the chuck table and the laser beam irradiation unit relative to each other to execute processing feed, and can divide a wafer into individual device chips with high accuracy.

However, particularly in a wafer in which copper interconnects are stacked on a silicon substrate, there is a problem that debris arising from melting and mixing of copper and silicon with each other due to irradiation with the laser beam adheres to a device and the quality of the device chip is deteriorated. In the debris, growing debris that grows over time after irradiation with the laser beam exists. The growing debris is readily generated when the workpiece contains a semiconductor material and a metal material.

Thus, the present assignee has developed a technique in which irradiation with a laser beam is executed again in order to break the growing debris generated at the outer circumferences of device chips (for example, refer to Japanese Patent Laid-open No. 2015-133437).

### SUMMARY OF THE INVENTION

However, in the technique disclosed in Japanese Patent Laid-open No. 2015-133437, irradiation with the laser beam for breaking the growing debris needs to be executed after irradiation with a laser beam for forming grooves in a workpiece is executed. Thus, there is room for improvement in the productivity.

Thus, an object of the present invention is to provide a laser processing apparatus and a laser processing method that can simultaneously execute irradiation with a laser beam for forming grooves in a workpiece and irradiation with a laser beam for breaking growing debris.

In accordance with an aspect of the present invention, there is provided a laser processing apparatus including a chuck table that holds a workpiece, a laser beam irradiation unit that irradiates the workpiece held by the chuck table with a pulsed laser beam, and a feed mechanism that moves the chuck table and the laser beam irradiation unit relative to each other to execute processing feed. The laser beam irradiation unit includes a laser oscillation mechanism that emits the pulsed laser beam and a beam condenser that condenses the pulsed laser beam emitted by the laser oscillation mechanism and irradiates the workpiece held by the chuck table with the pulsed laser beam. The laser oscillation mechanism includes a group setting part that sets a plurality of the pulsed laser beams into one group and a time interval setting part that sets a time interval of the pulsed laser beams that configure the one group, and sets a repetition frequency in such a manner as to regard the one group as one unit.

Preferably, the laser oscillation mechanism includes a plurality of laser diodes that emit the pulsed laser beams, the one group is set by the pulsed laser beams emitted by the plurality of laser diodes in the group setting part, and signals are input to the plurality of laser diodes at a desired time interval by a pulse delay generator in the time interval setting part.

Preferably, the laser oscillation mechanism includes a plurality of laser oscillators that emit the pulsed laser beams, the one group is set by the pulsed laser beams emitted by the plurality of laser oscillators in the group setting part, and a voltage is applied to the plurality of laser oscillators with delay by a desired time by a delayed voltage instrument in the time interval setting part.

Preferably, the repetition frequency is set by decimating a predetermined number of groups from among a plurality of groups from which the pulsed laser beams are emitted in one second.

In accordance with another aspect of the present invention, there is provided a laser processing method of executing processing of a workpiece by using a laser processing apparatus including a laser oscillation mechanism that includes a group setting part that sets a plurality of pulsed laser beams into one group and a time interval setting part that sets the time interval of the pulsed laser beams that configure the one group. The laser oscillation mechanism sets a repetition frequency in such a manner as to regard the one group as one unit. The laser processing method includes a groove forming step of forming grooves by ablation processing by irradiating the workpiece with the pulsed laser beams and a growing debris breaking step of breaking, by plasma, growing debris formed in the groove forming step. To simultaneously execute the growing debris breaking step in the groove forming step, the time interval of the pulsed laser beams is set in the time interval setting part in such a manner that irradiation with a next pulsed laser beam is executed within a time after which the plasma generated from the workpiece due to the irradiation with a pulsed laser beam disappears and the plasma continues to exist without being interrupted.

Preferably, the number of pulsed laser beams of the one group set in the group setting part is a sufficient number to break the growing debris and is such a number as to allow irradiation in a time beyond which molten debris is generated. Preferably, in the time interval setting part, a time interval between the one group and the other group that are adjacent to each other is set to a time interval equal to or longer than a time during which heat generated due to irradiation with the pulsed laser beams of the one group cools down.

According to the present invention, the irradiation with the laser beam for forming the grooves in the workpiece and the irradiation with the laser beam for breaking the growing debris can be simultaneously executed and thus the productivity can be improved.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view of a laser processing apparatus of an embodiment of the present invention;

FIG. 2 is a block diagram of the laser processing apparatus illustrated in FIG. 1;

FIG. 3 is a schematic diagram of a laser oscillation mechanism illustrated in FIG. 2;

FIG. 4 is a schematic diagram of the laser oscillation mechanism of another form;

FIG. 5 is a schematic diagram of pulsed laser beams with which a workpiece is irradiated; and

FIG. 6 is a schematic diagram illustrating the generation time and the disappearance time of plasma generated due to irradiation with the pulsed laser beam.

### DETAILED DESCRIPTION OF THE PREFERRED EMBODIMENT

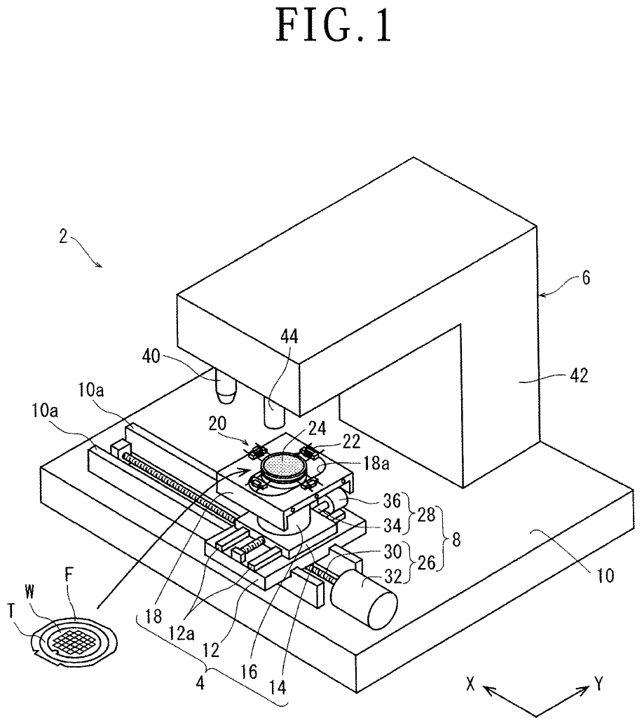

A laser processing apparatus and a laser processing method according to an embodiment of the present invention will be described below with respect to the drawings. First, the laser processing apparatus according to the present invention will be described. The laser processing apparatus indicated by numeral 2 as a whole in FIG. 1 includes a holding unit 4 that holds a workpiece such as a wafer, a laser beam irradiation unit 6 that irradiates the workpiece held by the holding unit 4 with a laser beam, and a feed mechanism 8 that moves the holding unit 4 and the laser beam irradiation unit 6 relative to each other to execute processing feed.

As illustrated in FIG. 1, the holding unit 4 includes an X-axis movable plate 12 supported by the upper surface of a base 10 movably in an X-axis direction, a Y-axis movable plate 14 supported by the upper surface of the X-axis movable plate 12 movably in a Y-axis direction, a support column 16 fixed to the upper surface of the Y-axis movable plate 14, and a cover plate 18 mounted on the upper end of the support column 16. A long hole 18a extending in the Y-axis direction is formed in the cover plate 18, and a chuck table 20 that passes through the long hole 18a and extends upward is rotatably mounted on the upper end of the support column 16. At the circumferential edge of the chuck table 20, multiple clamps 22 are disposed at intervals in the circumferential direction.

A porous circular suction adhesion chuck 24 connected to suction means (not illustrated) is disposed at an upper end part of the chuck table 20. In the holding unit 4, a suction force is generated for the upper surface of the suction adhesion chuck 24 by the suction means to hold the workpiece under suction. Furthermore, the chuck table 20 is allowed to be rotated by a motor (not illustrated) incorporated in the support column 16 with the upward-downward direction being the axial center.

The X-axis direction is a direction indicated by an arrow X in FIG. 1, and the Y-axis direction is a direction indicated by an arrow Y in FIG. 1 and is a direction orthogonal to the X-axis direction. The XY-plane defined by the X-axis direction and the Y-axis direction is substantially horizontal.

The feed mechanism 8 of the present embodiment includes an X-axis feed mechanism 26 that executes processing feed of the chuck table 20 in the X-axis direction and a Y-axis feed mechanism 28 that executes indexing feed of the chuck table 20 in the Y-axis direction.

The X-axis feed mechanism 26 has a ball screw 30 that is coupled to the X-axis movable plate 12 and extends in the X-axis direction and a motor 32 that rotates the ball screw 30. The X-axis feed mechanism 26 converts rotational motion of the motor 32 to linear motion by the ball screw 30 and transmits the linear motion to the X-axis movable plate 12 to move the X-axis movable plate 12 in the X-axis direction along guide rails 10a on the base 10. This causes processing feed of the chuck table 20 in the X-axis direction.

The Y-axis feed mechanism 28 has a ball screw 34 that is coupled to the Y-axis movable plate 14 and extends in the Y-axis direction and a motor 36 that rotates the ball screw 34. The Y-axis feed mechanism 28 converts rotational motion of the motor 36 to linear motion by the ball screw 34 and transmits the linear motion to the Y-axis movable plate 14 to move the Y-axis movable plate 14 in the Y-axis direction along guide rails 12a on the X-axis movable plate 12. This causes indexing feed of the chuck table 20 in the Y-axis direction.

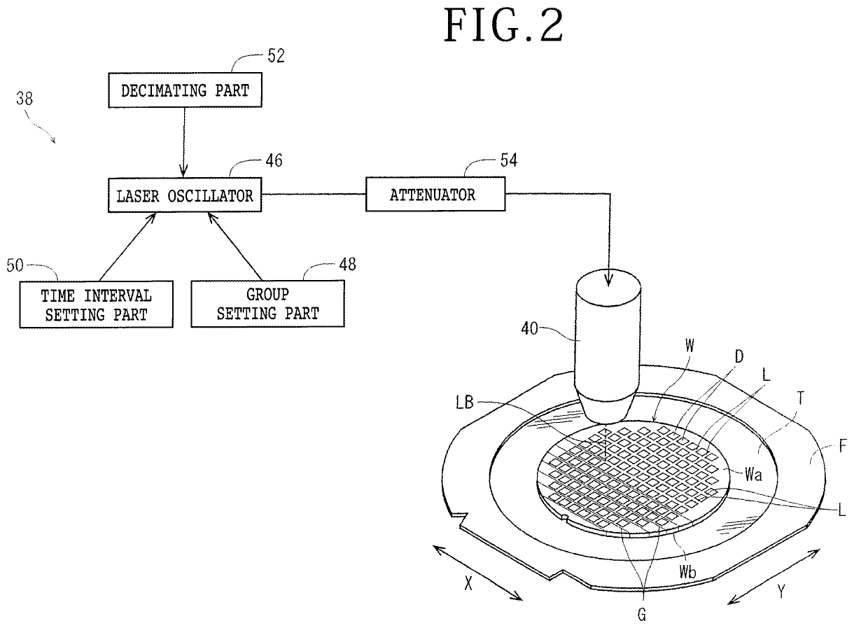

Referring to FIG. 1 and FIG. 2, the laser beam irradiation unit 6 includes a laser oscillation mechanism 38 (see FIG. 2) that emits a pulsed laser beam and a beam condenser 40 that condenses the pulsed laser beam emitted by the laser oscillation mechanism 38 and irradiates the workpiece held by the holding unit 4 with the pulsed laser beam.

As illustrated in FIG. 1, the laser beam irradiation unit 6 has a housing 42 that extends upward from the upper surface of the base 10 and subsequently extends substantially horizontally. The above-described laser oscillation mechanism 38 is housed inside the housing 42 and the above-described beam condenser 40 is mounted on the lower surface of the tip of the housing 42. Furthermore, an imaging unit 44 for imaging the workpiece held by the holding unit 4 is annexed on the lower surface of the tip of the housing 42.

As illustrated in FIG. 2, the laser oscillation mechanism 38 includes a laser oscillator 46 that emits the pulsed laser beam with a wavelength having absorbability with respect to the workpiece, a group setting part 48 that sets multiple pulsed laser beams into one group, and a time interval setting part 50 that sets the time interval of the pulsed laser beams that configure one group. The laser oscillation mechanism 38 includes also a decimating part 52 that decimates a predetermined number of groups from among multiple groups from which the pulsed laser beams are emitted by the laser oscillator 46 in one second and an attenuator 54 that adjusts the output power of the pulsed laser beams emitted by the laser oscillator 46. The laser oscillation mechanism 38 sets the repetition frequency in such a manner as to regard one group as one unit.

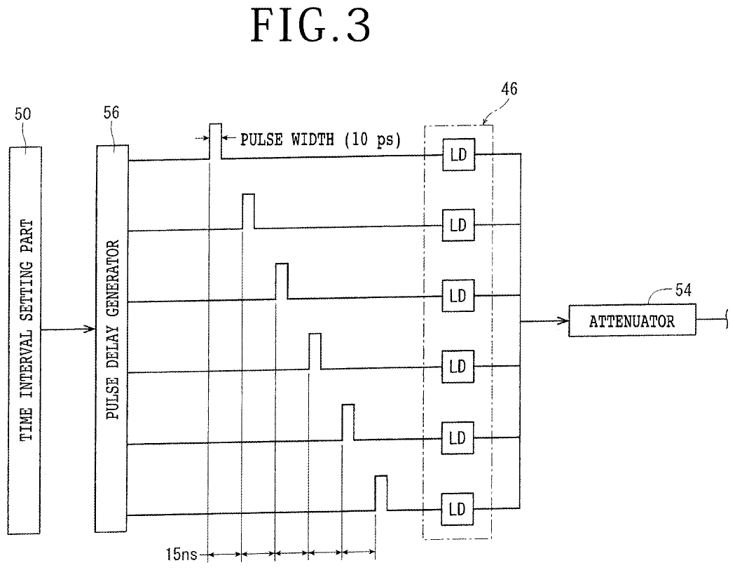

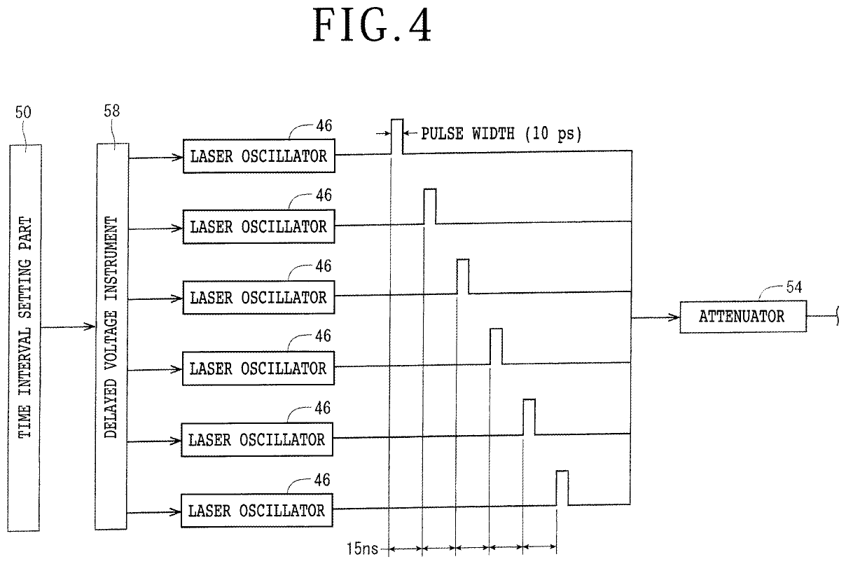

In FIG. 2, one box indicating the laser oscillator 46 is illustrated. However, the quantity of the laser oscillator 46 disposed in the laser oscillation mechanism 38 may be either one or more. When one laser oscillator 46 is disposed, one laser oscillator 46 can include multiple laser diodes LD as illustrated in FIG. 3, for example. Moreover, as illustrated in FIG. 4, multiple laser oscillators 46 may be disposed in the laser oscillation mechanism 38. The medium of the laser is not limited to a semiconductor and another publicly-known medium (for example, gas) can be employed.

The group setting part 48 can set one group by the pulsed laser beams emitted by the multiple laser diodes LD. As illustrated in FIG. 3, it is possible to set one group by the pulsed laser beams emitted by, for example, six laser diodes LD. The group setting part 48 may set one group by the pulsed laser beams emitted by part of the laser diodes LD (for example, four from among the six laser diodes LD) included in the laser oscillator 46.

Furthermore, the group setting part 48 may set one group by the pulsed laser beams emitted by the multiple laser oscillators 46. As illustrated in FIG. 4, it is also possible to set one group by the pulsed laser beams emitted by, for example, six laser oscillators 46. The group setting part 48 may set one group by the pulsed laser beams emitted by part of the laser oscillators 46 disposed in the laser oscillation mechanism 38.

In the case illustrated in FIG. 3, the time interval setting part 50 inputs signals to the multiple laser diodes LD at a desired time interval (for example, interval of 15 ns) by a pulse delay generator 56. Any value (for example, 10 ps) can be employed as the pulse width of the signals input from the pulse delay generator 56 to the respective laser diodes LD.

Moreover, in the case illustrated in FIG. 4, the time interval setting part 50 applies a voltage to the multiple laser oscillators 46 with delay by a desired time (for example, 15 ns) by a delayed voltage instrument 58. The pulse width of the pulsed laser beams emitted by the respective laser oscillators 46 due to the application of the voltage from the delayed voltage instrument 58 to the respective laser oscillators 46 may be any value (for example, 10 ps).

As described above, one group is set by the pulsed laser beams emitted from the six laser diodes LD in the example illustrated in FIG. 3 or the six laser oscillators 46 in the example illustrated in FIG. 4. Furthermore, in the decimating part 52, in both of the examples illustrated in FIG. 3 and FIG. 4, a predetermined number of groups are decimated from among multiple groups from which the pulsed laser beams are emitted by the six laser diodes LD or the six laser oscillators 46 in one second, in such a manner that one group is regarded as one unit.

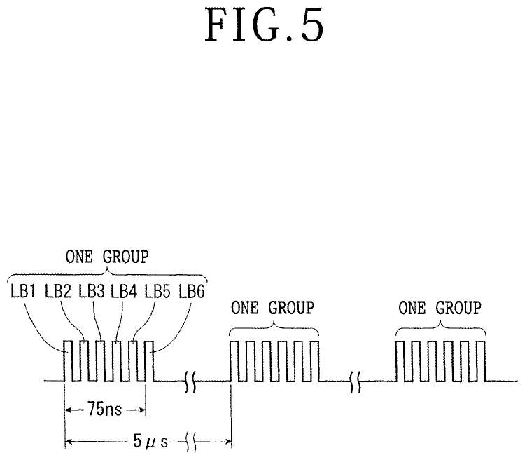

Thus, pulsed laser beams LB1 to LB6 about which one group (for example, six pulses) and another group have a predetermined time interval (for example, 5 ρs) like ones illustrated in FIG. 5 are generated. That is, the repetition frequency of the pulsed laser beams is set in such a manner that one group (six pulses) is regarded as one unit. When the time interval between one group and another group is 5 ρs as in the above-described example, the repetition frequency is set to 200 kHz. It suffices that the decimating part 52 be a configuration having an acousto-optical element or electro-optical element.

Moreover, the output power of the pulsed laser beams about which one group and another group have the predetermined time interval is adjusted by the attenuator 54. Thereafter, the pulsed laser beams are focused by the beam condenser 40 and the workpiece is irradiated with the pulsed laser beams. Light guide means such as an optical fiber is disposed between the laser oscillator 46 and the attenuator 54, and the pulsed laser beams of one group are guided from the laser oscillator 46 to the attenuator 54.

The laser oscillation mechanism 38 does not need to include the decimating part 52. For example, in the time interval setting part 50, the interval between one group and the next one group (interval between the first pulse of the one group and the first pulse of the next one group) may be set to 5 μs as described above.

In FIG. 2, a wafer W as a workpiece for which processing can be executed by a laser processing apparatus 2 is also illustrated. The wafer W with a circular plate shape can be formed from an appropriate semiconductor material such as silicon. A front surface Wa of the wafer W is segmented into multiple rectangular regions by planned dividing lines L in a lattice manner and a device D such as an IC or LSI is formed in each of the multiple rectangular regions. The front surface Wa of the wafer W is coated with a metal film of copper or the like although the metal film is not illustrated.

In the present embodiment, a back surface Wb of the wafer W is stuck to an adhesive tape T fixed to an annular frame F. However, the front surface Wa of the wafer W may be stuck to the adhesive tape T.

Next, the laser processing method according to the present invention will be described. In the present embodiment, first, a preparation step of preparing a laser processing apparatus (for example, the above-described laser processing apparatus 2) that executes irradiation with pulsed laser beams with a wavelength having absorbability with respect to a workpiece is executed.

After the preparation step is executed, a groove forming step of forming grooves by ablation processing by irradiating the workpiece with the pulsed laser beams is executed.

In the groove forming step, first, the front surface Wa of the wafer W is oriented upward and the wafer W is held under suction by the upper surface of the chuck table 20. Furthermore, the annular frame F is fixed by the clamps 22. Subsequently, the wafer W is imaged by the imaging unit 44 and the planned dividing lines L extending in a first direction are aligned with the X-axis direction on the basis of an image of the wafer W imaged by the imaging unit 44. Moreover, the aim of the pulsed laser beam is taken at one of the planned dividing lines L aligned with the X-axis direction and the height of the focal point of the pulsed laser beam is adjusted to the front surface Wa of the wafer W.

Next, while processing feed of the chuck table 20 is executed in the X-axis direction, the wafer W is irradiated with the pulsed laser beam with a wavelength having absorbability with respect to the wafer W from the beam condenser 40 and ablation processing is executed along the planned dividing line L. This forms a groove G (see FIG. 2) used for cutting the wafer W along the planned dividing line L.

Subsequently, indexing feed of the chuck table 20 is executed in the Y-axis direction relative to the beam condenser 40 by a distance equal to the interval of the planned dividing lines L in the Y-axis direction. Furthermore, by alternately repeating the irradiation with the pulsed laser beam and the indexing feed, the grooves G are formed in all of the planned dividing lines L aligned with the X-axis direction.

Next, after the chuck table 20 is rotated by 90 degrees, the irradiation with the pulsed laser beam and the indexing feed are alternately repeated. Thus, the grooves G are formed in all of the planned dividing lines L extending in a second direction orthogonal to the planned dividing lines L in which the grooves G have been formed previously. By executing the groove forming step in this manner, the grooves G are formed in a lattice manner along the planned dividing lines L in a lattice manner. This can divide the wafer W into individual device chips.

In the groove forming step, a growing debris breaking step of breaking, by plasma, growing debris formed in the groove forming step is simultaneously executed. For this purpose, in the growing debris breaking step, the time interval of the pulsed laser beams that configure one group is set by the time interval setting part 50 in such a manner that the workpiece is irradiated with the next pulsed laser beam within the time after which the plasma generated from the workpiece due to the irradiation with one pulsed laser beam disappears and the plasma continues to exist without being interrupted.

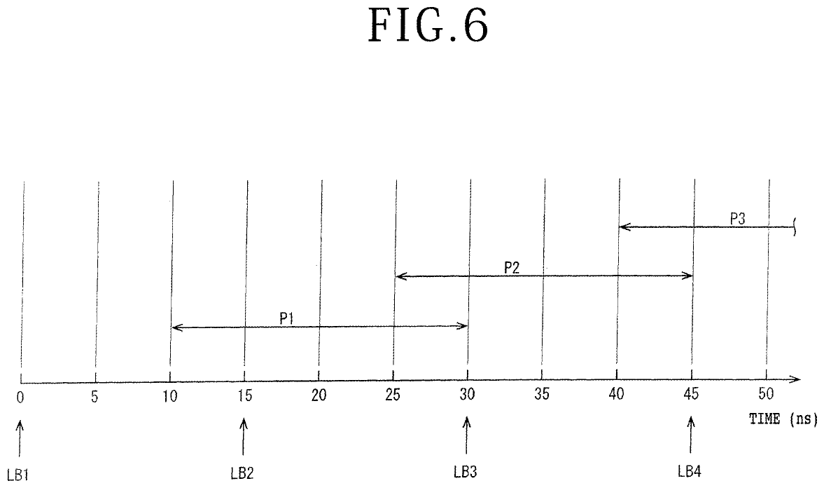

With reference to FIG. 6, description will be made regarding the time interval set by the time interval setting part 50 by taking as an example the case in which the time when the wafer W is irradiated with the first pulsed laser beam LB1 (first pulse) is regarded as the basis (0 s), plasma P1 is generated after 10 ns from the irradiation with the first pulse, and the plasma P1 disappears after 30 ns.

In such a case, in the time interval setting part 50, the time interval between the first pulse and the second pulse is set in such a manner that irradiation with the second pulsed laser beam LB2 (second pulse) is executed within the time (30 ns) after which the plasma P1 relating to the irradiation with the pulsed laser beam LB1 of the first pulse disappears.

For example, when the time interval between the first pulse and the second pulse is set to 15 ns, plasma P2 relating to the irradiation with the second pulse is generated after 25 ns from the irradiation with the first pulse and disappears after 45 ns. That is, the plasma P2 is generated before the plasma P1 disappears. Similarly, when the time interval between the second pulse and the third pulse is also set to 15 ns, plasma P3 relating to the third pulsed laser beam LB3 (third pulse) is generated before the plasma P2 disappears.

Thus, in the growing debris breaking step, the time interval setting part 50 inputs signals to the multiple laser diodes LD at an interval of 15 ns by the pulse delay generator 56 (see FIG. 3) or applies a voltage to the multiple laser oscillators 46 with delay by 15 ns by the delayed voltage instrument 58 (see FIG. 4).

As a result, the time interval between the pulses of the pulsed laser beams (for example, six pulsed laser beams LB1 to LB6) that configure one group becomes 15 ns, and the plasma continues to exist without being interrupted while the wafer W is irradiated with the pulsed laser beams of the one group. Therefore, the growing debris generated due to the irradiation with the pulsed laser beam can be surely broken by the plasma.

When the wafer W continues to be irradiated with the pulsed laser beams, it is concerned that a hot spot is generated in the wafer W and an adverse effect on the device (quality lowering of the device) attributed to heat is caused. Thus, it is preferable that, in the growing debris breaking step, the time interval between one group and adjacent one group be set by the time interval setting part 50 to a time interval equal to or longer than the time during which the heat generated due to irradiation with the pulsed laser beams of one group cools down.

It is known that, in a workpiece formed of a semiconductor material such as silicon, when 5 μs or longer has elapsed from irradiation with the pulsed laser beam, heat generated in the workpiece due to the irradiation with the pulsed laser beam cools down and the temperature of the workpiece lowers to almost the same temperature as that before the irradiation with the pulsed laser beam.

Thus, as illustrated in FIG. 5, it is desirable that, in the growing debris breaking step, the time interval between one group and adjacent one group be set by the time interval setting part 50 to a time interval equal to or longer than the time (5 μs) during which the heat generated due to irradiation with the pulsed laser beams of one group cools down.

Moreover, by decimating a predetermined number of groups from among multiple groups from which the pulsed laser beams are emitted in one second, by the decimating part 52 in such a manner that the time interval between one group and another group becomes the time interval set by the time interval setting part 50, the repetition frequency (for example, 200 kHz) is set in such a manner that one group is regarded as one unit. Due to this, heat generated in the wafer W cools down in the period from irradiation of the wafer W with the pulsed laser beams of one group to irradiation with the pulsed laser beams of the next one group. Thus, the quality lowering of the device due to the heat can be prevented.

Furthermore, it is preferable that, in the growing debris breaking step, the number of pulsed laser beams of one group set by the group setting part 48 be a sufficient number to break the growing debris and be such a number as to allow irradiation in the time beyond which molten debris is generated. As a sufficient number of pulsed laser beams to break the growing debris, for example, six pulses are enough.

Incidentally, in the present specification, in the debris generated in the workpiece due to irradiation with the pulsed laser beam, debris that grows over time (gradually becomes large after generation) will be referred to as the growing debris and debris that does not grow over time in contrast thereto will be referred to as the molten debris.

It has been confirmed that the molten debris is generated after the elapse of about 100 ns from irradiation of the workpiece with the pulsed laser beam and solidifies after the elapse of about 500 ns from the irradiation of the workpiece with the pulsed laser beam.

Thus, generation of the molten debris can be prevented by setting the time from irradiation with the first pulsed laser beam (first pulse) to irradiation with the last pulsed laser beam (for example, sixth pulse) in the pulsed laser beams of the same group to 100 ns or shorter.

In the example illustrated in FIG. 5, one group is composed of six pulsed laser beams and the time interval between the first pulse and the sixth pulse is 75 ns. Thus, generation of the molten debris can be prevented.

It is preferable that the number of pulsed laser beams that configure one group be set by the group setting part 48 in such a manner that heat generated due to irradiation with the pulsed laser beams of the one group results in at most such a temperature that the device is not adversely affected.

The above-described groove forming step and growing debris breaking step can be executed under the following processing condition, for example.
Wavelength of pulsed laser beam: 355 nm
Repetition frequency: 200 kHz
Average output power: 30 W
Configuration of one group: six pulsed laser beams
Power density of one group: 30 J/cm 2
Pulse width of one group: 75 ns (see FIG. 5)
Spot size of one group: 10 μm in the X-axis direction and 50 μm in the Y-axis direction
Overlapping rate between one group and another group: 50%
Feed rate: 1 m/s
Generation time of plasma: plasma is generated after 10 ns after laser irradiation (see FIG. 6)
Disappearance time of plasma: plasma disappears after 30 ns after laser irradiation (see FIG. 6)
Power density of one pulse: 5 J/cm 2
Pulse width of one pulse: 10 ps
Overlapping rate between pulses: 99.8%
Time interval between pulses: 15 ns (see FIG. 3 and FIG. 4)

It is preferable that the power density of the second and subsequent pulses among the pulses that configure one group be set to 80% or higher of the power density of the first pulse (may be the same power density as the first pulse or may be power density higher than it).

The configuration of the present embodiment is as above. In the present embodiment, the irradiation with the laser beam for forming the grooves in the workpiece and the irradiation with the laser beam for breaking the growing debris can be simultaneously executed and thus the productivity can be improved.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A laser processing apparatus comprising:
a chuck table that holds a workpiece;
a laser beam irradiation unit that irradiates the workpiece held by the chuck table with a pulsed laser beam; and
a feed mechanism that moves the chuck table and the laser beam irradiation unit relative to each other to execute processing feed,
wherein the laser beam irradiation unit includes:
a laser oscillation mechanism that emits the pulsed laser beam, and
a beam condenser that condenses the pulsed laser beam emitted by the laser oscillation mechanism and irradiates the workpiece held by the chuck table with the pulsed laser beam, and
the laser oscillation mechanism includes a group setting part that sets a plurality of the pulsed laser beams into one group and a time interval setting part that sets a time interval of the pulsed laser beams that configure the one group, and sets a repetition frequency in such a manner as to regard the one group as one unit.

2. The laser processing apparatus according to claim 1, wherein the laser oscillation mechanism includes a plurality of laser diodes that emit the pulsed laser beams,
the one group is set by the pulsed laser beams emitted by the plurality of laser diodes in the group setting part, and
signals are input to the plurality of laser diodes at a desired time interval by a pulse delay generator in the time interval setting part.

3. The laser processing apparatus according to claim 1, wherein the laser oscillation mechanism includes a plurality of laser oscillators that emit the pulsed laser beams,
the one group is set by the pulsed laser beams emitted by the plurality of laser oscillators in the group setting part, and
a voltage is applied to the plurality of laser oscillators with delay by a desired time by a delayed voltage instrument in the time interval setting part.

4. The laser processing apparatus according to claim 1, wherein the repetition frequency is set by decimating a predetermined number of groups from among a plurality of groups from which the pulsed laser beams are emitted in one second.

5. A laser processing method of executing processing of a workpiece by using a laser processing apparatus including a laser oscillation mechanism that includes a group setting part that sets a plurality of pulsed laser beams into one group and a time interval setting part that sets a time interval of the pulsed laser beams that configure the one group, the laser oscillation mechanism setting a repetition frequency in such a manner as to regard the one group as one unit, the laser processing method comprising:
a groove forming step of forming grooves by ablation processing by irradiating the workpiece with the pulsed laser beams; and
a growing debris breaking step of breaking, by plasma, growing debris formed in the groove forming step,
wherein to simultaneously execute the growing debris breaking step in the groove forming step, the time interval of the pulsed laser beams is set in the time interval setting part in such a manner that irradiation with a next pulsed laser beam is executed within a time after which the plasma generated from the workpiece due to the irradiation with a pulsed laser beam disappears and the plasma continues to exist without being interrupted.

6. The laser processing method according to claim 5, wherein the number of pulsed laser beams of the one group set in the group setting part is a sufficient number to break the growing debris and is such a number as to allow irradiation in a time beyond which molten debris is generated.

7. The laser processing method according to claim 5, wherein in the time interval setting part, a time interval between the one group and another group that are adjacent to each other is set to a time interval equal to or longer than a time during which heat generated due to irradiation with the pulsed laser beams of the one group cools down.
